(19) United States
(12) Patent Application Publication
(10) Pub. No.: US 2025/0208405 A1
(43) Pub. Date: Jun. 26, 2025

(54) MICROMIRROR DEVICE AND OPTICAL SCANNING DEVICE

(71) Applicant: FUJIFILM Corporation, Tokyo (JP)

(72) Inventors: Keisuke AOSHIMA, Kanagawa (JP); Takayuki NAONO, Kanagawa (JP)

(73) Assignee: FUJIFILM Corporation, Tokyo (JP)

(21) Appl. No.: 19/078,553

(22) Filed: Mar. 13, 2025

Related U.S. Application Data
(63) Continuation of application No. PCT/JP2023/031288, filed on Aug. 29, 2023.

(30) Foreign Application Priority Data
Sep. 28, 2022 (JP) 2022-155370

(51) Int. Cl. G02B 26/08; B81B 3/00; G02B 26/10

(52) U.S. Cl. CPC G02B 26/0858; B81B 3/0062; G02B 26/105; B81B 2201/042; B81B 2203/058; B81B 2207/03

(57) ABSTRACT

A micromirror device includes a mirror portion, a pair of first support portions, a pair of movable frames, a pair of second support portions, a fixed frame, a pair of first connecting portions, and a pair of second connecting portions. The movable frame is line-symmetrical with respect to the first axis and has a reinforcing structure that is not in contact with the boundary portion between the movable frame and the first support portion, and the first connecting portion and the second connecting portion each have a line-symmetrical shape with respect to the first axis and support the first actuator and the second actuator to be swingable around the first axis.

### CROSS-REFERENCE TO RELATED APPLICATIONS

This application is a continuation application of International Application No. PCT/JP2023/031288, filed Aug. 29, 2023, the disclosure of which is incorporated herein by reference in its entirety. Further, this application claims priority from Japanese Patent Application No. 2022-155370, filed on Sep. 28, 2022, the disclosure of which is incorporated herein by reference in its entirety.

### BACKGROUND

### 1. Technical Field

The technique of the present disclosure relates to a micromirror device and an optical scanning device.

### 2. Description of the Related Art

A micromirror device (also referred to as a microscanner) is known as one of micro electro mechanical systems (MEMS) devices manufactured using the silicon (Si) nanofabrication technique. Since the micromirror device is small and has low power consumption, it is expected to have a wide range of applications in laser displays, laser projectors, optical coherence tomography, and the like.

In recent years, there has been an increasing demand for a light detection and ranging (LiDAR) device that scans light in all directions of 360 degrees as a self-position detection device in a low-speed moving object such as a drone. In addition, attention is focused on a LiDAR device equipped with an optical scanning device having a micromirror device capable of performing helical scanning.

There are various methods for driving the micromirror device, and a piezoelectric drive type using deformation of a piezoelectric material is promising since the generated rotational torque is higher than that in other methods and a high scan angle can be obtained. In addition, a larger scan angle can be obtained by driving the micromirror device of the piezoelectric drive type in a resonance manner.

A general micromirror device comprises a mirror portion and a piezoelectric drive type actuator (for example, see JP2017-132281A). The mirror portion is swingable around a first axis and a second axis that are orthogonal to each other. The actuator is a driving part that causes the mirror portion to swing around a first axis and a second axis in accordance with a driving voltage supplied from the outside. For example, the mirror portion performs precession by swinging around the first axis and the second axis.

### SUMMARY

Examples of the performance indicator of the distance measurement by the LiDAR device include a detection distance, a resolution, and a detection range. These performance indicators are greatly affected by the diameter, the operation frequency, and the deflection angle of the mirror portion. In the LiDAR device, the scanned light is reflected by the object and the return light is then reflected by the mirror portion and guided to the light-receiving element. Therefore, as the diameter of the mirror portion increases, the amount of the reflected return light increases, and the detection distance increases. In addition, the higher the operation frequency, the higher the resolution. Further, since the scan angle increases as the deflection angle of the mirror portion increases, the detection range increases. The operation frequency refers to a rotation frequency of the mirror portion that performs precession.

However, in principle, in a case where the diameter of the mirror portion is increased, the inertia moment of the mirror is increased, so that the resonance frequency is decreased and the deflection angle is decreased. That is, in principle, in a case where the diameter of the mirror portion is increased, the operation frequency and the deflection angle are decreased, and the resolution and the detection range of the LiDAR device are decreased.

In addition, in order to perform the helical scanning, a swing frequency of the mirror portion around the first axis and a swing frequency of the mirror portion around the second axis need to substantially match each other. However, since the micromirror device supports the mirror portion by a so-called gimbal structure, a difference in resonance frequency occurs between the first axis and the second axis due to an inertia moment of the gimbal structure. This difference becomes larger as the gimbal structure becomes larger. On the other hand, in the thin gimbal structure, the gimbal structure itself is largely distorted during the rotation of the mirror portion, and the resonance frequency and the deflection angle are largely decreased.

An object of the technology of the present disclosure is to provide a micromirror device and an optical scanning device that can increase a diameter, an operation frequency, and a deflection angle of a mirror portion.

In order to achieve the above object, a micromirror device of the present disclosure comprises: a mirror portion that has a reflecting surface for reflecting incident light; a pair of first support portions that are connected to the mirror portion on a first axis located in a plane including the reflecting surface in a stationary state of the mirror portion and that support the mirror portion to be swingable around the first axis; a pair of movable frames that are connected to the first support portions and that face each other across the first axis; a pair of second support portions that are connected to the movable frames on a second axis located in the plane and perpendicular to the first axis and that support the mirror portion, the first support portions, and the movable frames to be swingable around the second axis; a pair of first actuators that are connected to the second support portions and face each other across the second axis; a pair of second actuators that are disposed to surround the first actuator and face each other across the first axis; a fixed frame that is disposed to surround the second actuator; a pair of first connecting portions that connect the first actuator and the second actuator; and a pair of second connecting portions that connect the second actuator and the fixed frame, in which the movable frame is line-symmetrical with respect to the first axis and has a reinforcing structure that is not in contact with a boundary portion between the movable frame and the first support portion, and the first connecting portion and the second connecting portion each have a line-symmetrical shape with respect to the first axis and support the first actuator and the second actuator to be swingable around the first axis.

It is preferable that a combined thickness of the movable frame and the reinforcing structure is equal to a thickness of the fixed frame.

It is preferable that the reinforcing structure is provided on a back surface side of the movable frame.

It is preferable that the first actuator and the second actuator each have a piezoelectric element.

It is preferable that the first support portion includes a first swing shaft having a shape that is line-symmetrical about the first axis and disposed on the first axis, and a pair of first coupling parts disposed at positions facing each other across the first axis, one end of the first swing shaft is connected to the mirror portion and the other end of the first swing shaft is connected to the first coupling part, and one end of the first coupling part is connected to an outer end portion of the first swing shaft on the first axis and the other end of the first coupling part is connected to the movable frame.

It is preferable that the first coupling part extends in a direction from the outer end portion of the first swing shaft on the first axis toward the mirror portion, is bent in an outer circumferential direction in a region adjacent to the mirror portion, and is bent again in a region adjacent to the first actuator to be connected to the movable frame.

It is preferable that the second support portion includes a second swing shaft having a shape that is line-symmetrical about the second axis and disposed on the second axis, and a pair of second coupling parts disposed at positions facing each other across the second axis, one end of the second swing shaft is connected to the movable frame and the other end of the second swing shaft is connected to the second coupling part, and one end of the second coupling part is connected to an outer end portion of the second swing shaft on the second axis and the other end of the second coupling part is connected to the first actuator.

It is preferable that the second coupling part extends in a direction from the outer end portion of the second swing shaft on the second axis toward the mirror portion, is bent in an outer circumferential direction in a region adjacent to the movable frame, and is connected to the first actuator in a region adjacent to the second actuator.

An optical scanning device of the present disclosure comprises: the micromirror device described above; and a processor that drives the first actuator and the second actuator, in which the processor applies a drive signal to the first actuator and the second actuator to cause the mirror portion to swing around each of the first axis and the second axis.

According to the technology of the present disclosure, it is possible to provide a micromirror device and an optical scanning device that can increase the diameter, the operation frequency, and the deflection angle of a mirror portion.

### BRIEF DESCRIPTION OF THE DRAWINGS

Exemplary embodiments according to the technique of the present disclosure will be described in detail based on the following figures, wherein:

FIG. 1 is a schematic view of an optical scanning device,

FIG. 2 is a block diagram showing an example of a hardware configuration of a driving controller,

FIG. 3 is a plan view of the micromirror device according to the first embodiment as viewed from a light incident side,

FIG. 4 is a perspective view of the micromirror device according to the first embodiment as viewed from a back surface side,

FIG. 5 is a cross-sectional view taken along the line A-A of FIG. 3,

FIGS. 6(A) and 6(B) are diagrams showing examples of a first drive signal and a second drive signal,

FIG. 7 is a diagram showing a state in which the mirror portion performs precession,

FIG. 8 is a diagram showing parameters relating to dimensions of components of the micromirror device,

FIG. 9 is a diagram showing parameters relating to dimensions of components of the micromirror device,

FIG. 10 is a diagram showing specific set values of the parameters,

FIG. 11 is a plan view of a micromirror device according to a second embodiment as viewed from a light incident side,

FIG. 12 is a perspective view of the micromirror device according to the second embodiment as viewed from a back surface side,

FIG. 13 is a diagram showing parameters relating to dimensions of components of the micromirror device,

FIG. 14 is a diagram showing parameters relating to dimensions of components of the micromirror device,

FIG. 15 is a diagram showing specific set values of the parameters,

FIG. 16 is a plan view of a micromirror device according to a first comparative example as viewed from a light incident side,

FIG. 17 is a perspective view of a micromirror device according to a first comparative example as viewed from a back surface side,

FIG. 18 is a diagram showing parameters relating to dimensions of components of the micromirror device,

FIG. 19 is a diagram showing parameters relating to dimensions of components of the micromirror device,

FIG. 20 is a diagram showing specific set values of the parameters,

FIG. 21 is a plan view of a micromirror device according to a second comparative example as viewed from a light incident side,

FIG. 22 is a perspective view of a micromirror device according to a second comparative example as viewed from a back surface side,

FIG. 23 is a diagram showing parameters relating to dimensions of components of the micromirror device,

FIG. 24 is a diagram showing parameters relating to dimensions of components of the micromirror device,

FIG. 25 is a diagram showing specific set values of the parameters,

FIG. 26 is a stress distribution diagram showing a distribution of a stress in the vicinity of a boundary portion generated by a simulation, and

FIG. 27 is a diagram showing experimental results according to each of the embodiments and comparative examples described above.

### DETAILED DESCRIPTION

An example of an embodiment according to the technology of the present disclosure will be described with reference to the accompanying drawings.

### First Embodiment

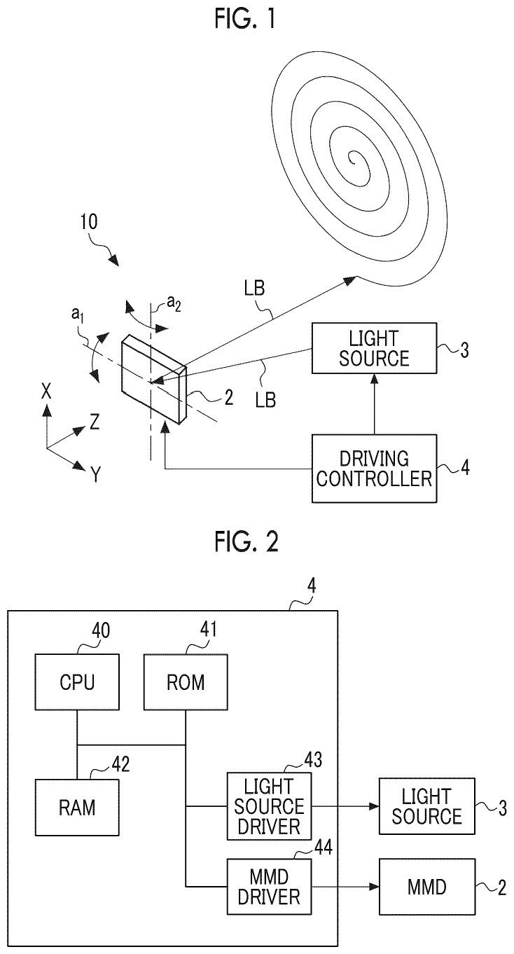

FIG. 1 is a schematic view of an optical scanning device 10 according to the first embodiment. The optical scanning device 10 includes a micromirror device (hereinafter, referred to as MMD) 2, a light source 3, and a driving controller 4. The optical scanning device 10 is mounted on, for example, a LiDAR device.

The optical scanning device 10 reflects the light beam LB emitted from the light source 3 by the MMD 2 under the control of the driving controller 4 to scan the light beam LB in a helical trajectory. The helical trajectory includes a spiral trajectory in which the radius vector changes and a circular trajectory in which the radius vector is constant.

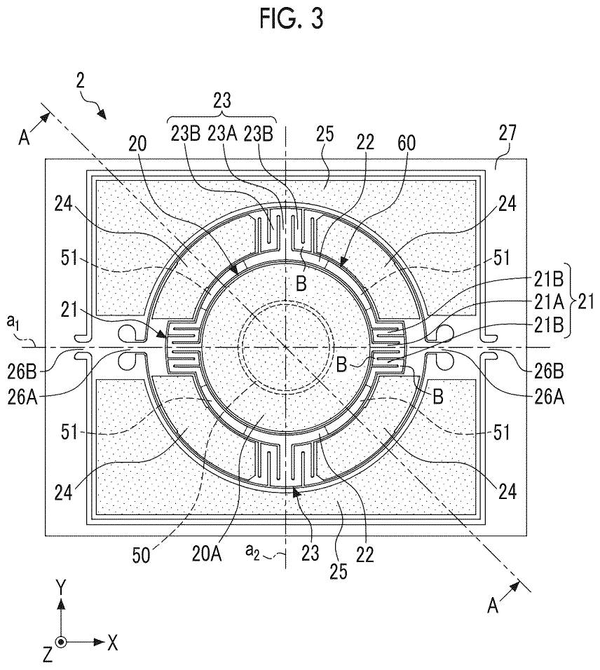

The MMD 2 is a piezoelectric biaxial drive-type micromirror device capable of allowing a mirror portion 20 (see FIG. 3) to swing around a first axis a₁ and a second axis a₂ perpendicular to the first axis a₁. Hereinafter, a direction parallel to the first axis a₁ is referred to as an X direction, a direction parallel to the second axis a₂ is a Y direction, and a direction perpendicular to the first axis a₁ and the second axis a₂ is referred to as a Z direction.

The light source 3 is a laser device that emits, for example, laser light as the light beam LB. It is preferable that the light source 3 emits the light beam LB perpendicularly to a reflecting surface 20A (see FIG. 3) included in the mirror portion 20 in a state where the mirror portion 20 of the MMD 2 is stationary.

The driving controller 4 outputs a drive signal to the light source 3 and the MMD 2. The light source 3 generates the light beam LB based on the input drive signal and emits the light beam LB to the MMD 2. The MMD 2 allows the mirror portion 20 to swing around the first axis a₁ and the second axis a₂ based on the input drive signal.

Although described in detail below, the driving controller 4 rotates the mirror portion 20 by causing the mirror portion 20 to resonate around each of the first axis a₁ and the second axis a₂. The light beam LB reflected by the mirror portion 20 is scanned in a helical trajectory. This optical scanning method is called a helical scanning method.

The optical scanning device 10 can be applied to, for example, a LiDAR device. The LiDAR device is mounted on a low-speed moving object such as a drone. In the LiDAR device, the scanned light beam LB is reflected by the object and the return light is then reflected by the mirror portion 20 and guided to the light-receiving element (not shown). Therefore, as the diameter of the mirror portion 20 increases, the amount of the reflected return light increases, and the detection distance of the distance measurement by the LiDAR device increases.

FIG. 2 shows an example of a hardware configuration of the driving controller 4. The driving controller 4 has a central processing unit (CPU) 40, a read only memory (ROM) 41, a random access memory (RAM) 42, a light source driver 43, and an MMD driver 44. The CPU 40 is an arithmetic unit that realizes the entire function of the driving controller 4 by reading out a program and data from a storage device such as the ROM 41 into the RAM 42 and executing processing. The CPU 40 is an example of a “processor” according to the technology of the present disclosure.

The ROM 41 is a non-volatile storage device and stores data such as a program for the CPU 40 to execute processing. The RAM 42 is a volatile storage device that temporarily holds a program and data.

The light source driver 43 is an electric circuit that outputs a drive signal to the light source 3 under the control of the CPU 40. In the light source driver 43, the drive signal is a driving voltage for controlling the irradiation timing and the irradiation intensity of the light source 3.

The MMD driver 44 is an electric circuit that outputs a drive signal to the MMD 2 under the control of the CPU 40. In the MMD driver 44, the drive signal is a driving voltage for controlling the timing, operation frequency, and deflection angle for allowing the mirror portion 20 of the MMD 2 to swing.

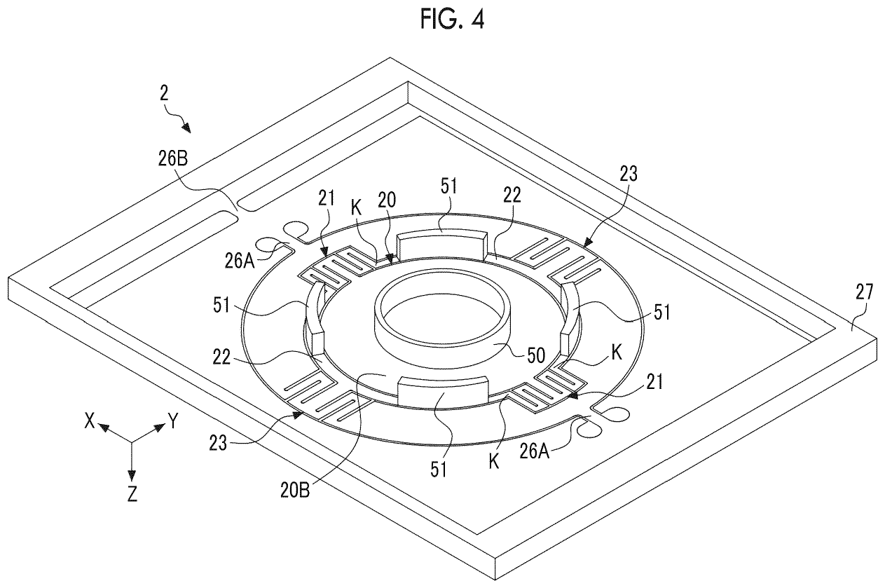

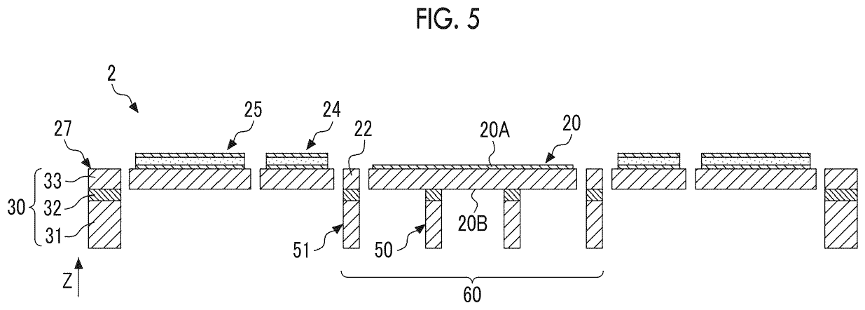

Next, the configuration of the MMD 2 according to a first embodiment will be described with reference to FIGS. 3 to 5. FIG. 3 is a plan view of the MMD 2 as viewed from the light incident side. FIG. 4 is a perspective view of the MMD 2 as viewed from a back surface side. FIG. 5 is a cross-sectional view schematically showing a cross section taken along line A-A of FIG. 3.

As shown in FIG. 3, the MMD 2 has the mirror portion 20, a pair of first support portions 21, a pair of movable frames 22, a pair of second support portions 23, a pair of first actuators 24, a pair of second actuators 25, a pair of first connecting portions 26A, a pair of second connecting portions 26B, and a fixed frame 27. The MMD 2 is a so-called MEMS scanner.

The mirror portion 20 has a reflecting surface 20A for reflecting incident light. The reflecting surface 20A is provided on one surface of the mirror portion 20, and is formed of a metal thin film such as gold (Au) and aluminum (Al). The shape of the reflecting surface 20A is, for example, circular with the intersection of the first axis a₁ and the second axis a₂ as the center.

The first axis a₁ and the second axis a₂ exist, for example, in a plane including the reflecting surface 20A in a case where the mirror portion 20 is stationary. The planar shape of the MMD 2 is rectangular, line-symmetrical about the first axis a₁, and line-symmetrical about the second axis a₂.

The pair of first support portions 21 are disposed at positions facing each other across the second axis a₂, and have a shape that is line-symmetrical about the second axis a₂. In addition, each of the first support portions 21 has a shape that is line-symmetrical about the first axis a₁. The first support portions 21 are connected to the mirror portion 20 on the first axis a₁, and swingably support the mirror portion 20 around the first axis a₁.

The pair of movable frames 22 are disposed at positions facing each other across the first axis a₁, and have a shape that is line-symmetrical about the first axis a₁. Each of the movable frames 22 has a shape that is line-symmetrical about the second axis a₂. In addition, each of the movable frames 22 is curved along the outer periphery of the mirror portion 20. Both ends of the movable frame 22 are connected to the first support portion 21.

The first support portion 21 and the movable frame 22 are connected to each other to surround the mirror portion 20. The mirror portion 20, the first support portion 21, and the movable frame 22 constitute a movable portion 60.

The pair of second support portions 23 are disposed at positions facing each other across the first axis a₁, and have a shape that is line-symmetrical about the first axis a₁. Each of the second support portions 23 has a shape that is line-symmetrical about the second axis a₂. The second support portion 23 is connected to the movable frame 22 on the second axis a₂, and swingably supports the movable portion 60 having the mirror portion 20 around the second axis a₂. In addition, both ends of the second support portion 23 are connected to the first actuator 24.

The pair of first actuators 24 are disposed at positions facing each other across the second axis a₂, and have a shape that is line-symmetrical about the second axis a₂. In addition, the first actuators 24 have a shape that is line-symmetrical about the first axis a₁. The first actuator 24 is formed along the outer periphery of the movable frame 22 and the first support portion 21. The first actuator 24 is a piezoelectric drive type actuator comprising a piezoelectric element.

The first actuator 24 is electrically connected across the first axis a₁ by a wiring line (not shown). The pair of first actuators 24 disposed across the second axis a₂ are electrically separated.

The second support portion 23 and the first actuator 24 are connected to each other to surround the movable portion 60.

The pair of second actuators 25 are disposed at positions facing each other across the first axis a₁, and have a shape that is line-symmetrical about the first axis a₁. In addition, the second actuators 25 have a shape that is line-symmetrical about the second axis a₂. The second actuator 25 is formed along the outer periphery of the first actuator 24 and the second support portion 23. The second actuator 25 is a piezoelectric drive type actuator comprising a piezoelectric element.

The pair of second actuators 25 disposed across the first axis a₁ are electrically separated.

The pair of first connecting portions 26A are disposed at positions facing each other across the second axis a₂, and have a shape that is line-symmetrical about the second axis a₂. In addition, each of the first connecting portions 26A is stretched in the X direction and has a shape that is line-symmetrical about the first axis a₁. The first connecting portion 26A is disposed along the first axis a₁, and connects the first actuator 24 and the second actuator 25 on the first axis a₁.

The pair of second connecting portions 26B are disposed at positions facing each other across the second axis a₂, and have a shape that is line-symmetrical about the second axis a₂. In addition, each of the second connecting portions 26B is stretched in the X direction, and has a shape that is line-symmetrical about the first axis a₁. The second connecting portion 26B is disposed along the second axis a₂, and connects the second actuator 25 and the fixed frame 27 on the first axis a₁.

The second actuator 25 is disposed to surround the first actuator 24. The first actuator 24 and the second actuator 25 constitute a driving part surrounding the movable frame 22. The first connecting portion 26A and the second connecting portion 26B support the first actuator 24 and the second actuator 25 to be swingable around the first axis a₁.

The fixed frame 27 is a frame-shaped member having a rectangular outer shape, and has a shape that is line-symmetrical about each of the first axis a₁ and the second axis a₂. The fixed frame 27 is disposed to surround the second actuator 25.

The first actuator 24 and the second actuator 25 are piezoelectric actuators each including a piezoelectric element. The pair of first actuators 24 allow the movable portion 60 to swing around the second axis a₂ by applying rotational torque around the second axis a₂ to the mirror portion 20 and the movable frame 22. The pair of second actuators 25 allow the mirror portion 20 to swing around the first axis a₁ by applying rotational torque around the first axis a₁ to the mirror portion 20, the movable frame 22, and the first actuator 24.

The first support portion 21 is composed of a swing shaft 21A and a pair of coupling parts 21B. The swing shaft 21A is a so-called torsion bar extended along the first axis a₁. One end of the swing shaft 21A is connected to the mirror portion 20, and the other end of the swing shaft 21A is connected to the coupling part 21B.

The pair of coupling parts 21B are disposed at positions facing each other across the first axis a₁, and have a shape that is line-symmetrical about the first axis a₁. One end of the coupling part 21B is connected to an outer end portion of the swing shaft 21A on the first axis a₁, and the other end of the coupling part 21B is connected to the movable frame 22. The coupling part 21B has a folded structure (so-called meandering structure).

Specifically, the coupling part 21B extends from the outer end portion of the swing shaft 21A on the first axis a₁ toward the mirror portion 20 and is bent in the outer circumferential direction in a region adjacent to the mirror portion 20. Further, the coupling part 21B extends in the outer circumferential direction and is bent in a region adjacent to the first actuator 24. The coupling part 21B extends in a direction toward the mirror portion 20 and is connected to the movable frame 22. That is, the coupling part 21B has two bent portions B. As described above, since the coupling part 21B has elasticity due to the folded structure, the internal stress applied to the swing shaft 21A is relaxed in a case where the mirror portion 20 swings around the first axis a₁. The swing shaft 21A and the coupling part 21B correspond to a “first swing shaft” and a “first coupling part” according to the technology of the present disclosure, respectively.

The second support portion 23 is composed of a swing shaft 23A and a pair of coupling parts 23B. The swing shaft 23A is a so-called torsion bar extended along the second axis a₂. One end of the swing shaft 23A is connected to the movable frame 22, and the other end thereof is connected to the coupling part 23B.

The pair of coupling parts 23B are disposed at positions facing each other across the second axis a₂, and have a shape that is line-symmetrical about the second axis a₂. One end of the coupling part 23B is connected to an outer end portion of the swing shaft 23A on the second axis a₂, and the other end of the coupling part 23B is connected to the first actuator 24. The coupling part 23B has a folded structure.

Specifically, the coupling part 23B extends from the outer end portion of the swing shaft 23A on the second axis a₂ toward the mirror portion 20 and is bent in the outer circumferential direction in a region adjacent to the movable frame 22. Further, the coupling part 23B extends in the outer circumferential direction and is connected to the first actuator 24 in a region adjacent to the second actuator 25. That is, the coupling part 23B has one bent portion B. As described above, since the coupling part 23B has elasticity due to the folded structure, the internal stress applied to the swing shaft 23A is relaxed in a case where the mirror portion 20 swings around the second axis a₂. The swing shaft 23A and the coupling part 23B correspond to a “second swing shaft” and a “second coupling part” according to the technology of the present disclosure, respectively.

As described above, the mirror portion 20 is supported to be swingable around the first axis a₁ and the second axis a₂ by the gimbal structure including the movable frame 22.

In FIG. 3, wiring lines and electrode pads for providing drive signals to the first actuators 24 and the second actuators 25 are not shown. A plurality of the electrode pads are provided on the fixed frame 27.

As shown in FIG. 4, a rib 50 is provided on the back surface 20B of the mirror portion 20. The back surface 20B is a surface opposite to the reflecting surface 20A. The rib 50 has an annular structure concentric with the mirror portion 20. The ribs 50 are provided mainly for the purpose of bringing the resonance frequency around the first axis a₁ of the mirror portion 20 and the resonance frequency around the second axis a₂ of the mirror portion 20 close to each other. In the present embodiment, the shape of the rib 50 is substantially circular.

In addition, a reinforcing structure 51 is provided on a back surface side of the movable frame 22. The back surface of the movable frame 22 is a surface on the same side as the back surface 20B of the mirror portion 20. In the present embodiment, two reinforcing structures 51 are provided on the back surface of each of the pair of movable frames 22. The four reinforcing structures 51 have a line-symmetrical shape with respect to each of the first axis a₁ and the second axis a₂. Each of the reinforcing structures 51 is disposed between the second support portion 23 and the first support portion 21 on the back surface of the movable frame 22. However, each of the reinforcing structures 51 does not extend to the boundary portion K between the movable frame 22 and the first support portion 21 and does not come into contact with the boundary portion K.

As shown in FIG. 5, the MMD 2 is formed, for example, by performing an etching treatment on a silicon on insulator (SOI) substrate 30. The SOI substrate 30 is a substrate in which a silicon oxide layer 32 is provided on a first silicon active layer 31 made of single crystal silicon, and a second silicon active layer 33 made of single crystal silicon is provided on the silicon oxide layer 32.

The mirror portion 20, the first support portion 21, the movable frame 22, the second support portion 23, the first actuator 24, the second actuator 25, the first connecting portion 26A, and the second connecting portion 26B are formed of the second silicon active layer 33 remaining by removing the first silicon active layer 31 and the silicon oxide layer 32 from the SOI substrate 30 by an etching treatment. The second silicon active layer 33 functions as an elastic portion having elasticity. The fixed frame 27 is formed of three layers of the first silicon active layer 31, the silicon oxide layer 32, and the second silicon active layer 33. That is, the mirror portion 20, the first support portion 21, the movable frame 22, the second support portion 23, the first actuator 24, the second actuator 25, the first connecting portion 26A, and the second connecting portion 26B have a thinner thickness than the fixed frame 27. In the present disclosure, the thickness means a width in the Z direction.

The rib 50 is formed by etching the first silicon active layer 31 and the silicon oxide layer 32. Similarly, the reinforcing structure 51 is formed by etching the first silicon active layer 31 and the silicon oxide layer 32. The thickness of the rib 50 and the thickness of the reinforcing structure 51 are the same. In addition, the combined thickness of the movable frame 22 and the reinforcing structure 51 is equal to the thickness of the fixed frame 27.

The first actuator 24 includes a piezoelectric element formed on the second silicon active layer 33. The piezoelectric element has a laminated structure in which a lower electrode, a piezoelectric film, and an upper electrode are sequentially laminated on the second silicon active layer 33. The second actuator 25 has the same configuration as the first actuator 24.

The lower electrode and the upper electrode are formed of, for example, metal such as gold (Au) or platinum (Pt). The piezoelectric film is formed of, for example, lead zirconate titanate (PZT), which is a piezoelectric material. The lower electrode and the upper electrode are electrically connected to the driving controller 4 described above via the wiring line and the electrode pad.

The lower electrode is connected to the driving controller 4 via the wiring line and the electrode pad, and a ground potential is applied thereto. A driving voltage is applied to the upper electrode from the driving controller 4.

In a case where a positive or negative voltage is applied to the piezoelectric film in the polarization direction, deformation (for example, expansion and contraction) proportional to the applied voltage occurs. That is, the piezoelectric film exerts a so-called inverse piezoelectric effect. The piezoelectric film exerts an inverse piezoelectric effect by applying a driving voltage from the driving controller 4 to the upper electrode, and displaces the first actuator 24 and the second actuator 25.

By extending one piezoelectric film of the pair of second actuators 25 and contracting the other piezoelectric film, a rotational torque around the first axis a₁ is generated in the second actuator 25. In this way, one of the pair of second actuators 25 and the other are displaced in opposite directions to each other, whereby the mirror portion 20 rotates around the first axis a₁.

In the present embodiment, the second actuator 25 is driven in an anti-phase resonance mode (hereinafter, referred to as an anti-phase rotation mode) in which the displacement direction of the pair of second actuators 25 and the rotation direction of the mirror portion 20 are opposite to each other.

A deflection angle of the mirror portion 20 around the first axis a₁ is controlled by the drive signal (hereinafter, referred to as a first drive signal) given to the second actuator 25 by the driving controller 4. The first drive signal is, for example, a sinusoidal AC voltage. The first drive signal includes a driving voltage waveform V_{1A} (t) applied to one of the pair of second actuators 25 and a driving voltage waveform V_{1B} (t) applied to the other. The driving voltage waveform V_{1A} (t) and the driving voltage waveform V_{1B} (t) are in an anti-phase with each other (that is, the phase difference is) 180°.

The first actuator 24 is driven in the anti-phase rotation mode similarly to the second actuator 25. A deflection angle of the mirror portion 20 around the second axis a₂ is controlled by the drive signal (hereinafter, referred to as a second drive signal) given to the first actuator 24 by the driving controller 4. The second drive signal is, for example, a sinusoidal AC voltage. The second drive signal includes a driving voltage waveform V_{2A} (t) applied to one of the pair of first actuators 24 and a driving voltage waveform V_{2B} (t) applied to the other. The driving voltage waveform V_{2A} (t) and the driving voltage waveform V_{2B} (t) are in an anti-phase with each other (that is, the phase difference is 180°).

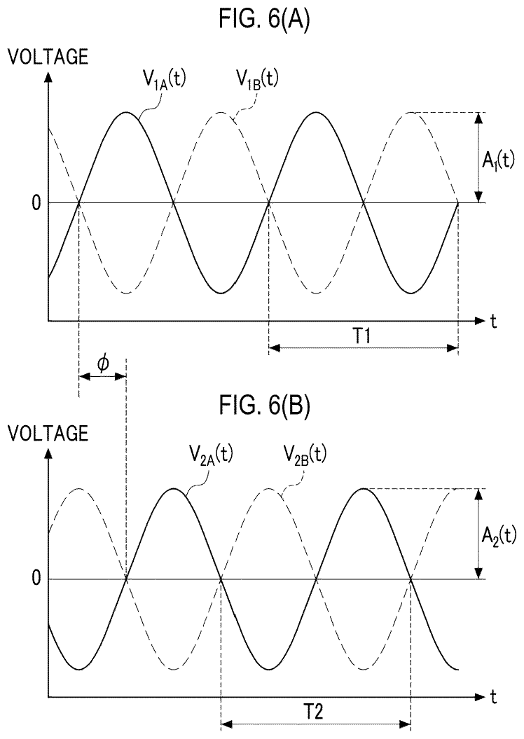

FIGS. 6(A) and 6(B) show examples of the first drive signal and the second drive signal. FIG. 6(A) shows the driving voltage waveforms V_{1A} (t) and V_{1B} (t) included in the first drive signal. FIG. 6(B) shows the driving voltage waveforms V_{2A} (t) and V_{2B} (t) included in the second drive signal.

The driving voltage waveforms V_{1A} (t) and V_{1B} (t) are represented as follows, respectively.

$${V}_{1 A} ( t ) = {A}_{1} ( t ) sin ( 2 π {f}_{d 1} t )$$

$${V}_{1 B} ( t ) = {A}_{1} ( t ) sin ( 2 π {f}_{d 1} t + π )$$

Here, t is a time. f_{d1} is the driving frequency (hereinafter, referred to as the first driving frequency). A₁ (t) is an amplitude voltage that changes depending on time t. A phase difference between the driving voltage waveform V_{1A} (t) and the driving voltage waveform V_{1B} (t) is π (that is, 180°).

By applying the driving voltage waveforms V_{1A} (t) and V_{1B} (t) to the pair of second actuators 25, the mirror portion 20 swings around the first axis a₁ with a period T1(=1/f_{d1}).

The driving voltage waveforms V_{2A} (t) and V_{2B} (t) are represented as follows, respectively.

$${V}_{2 A} ( t ) = {A}_{2} ( t ) sin ( 2 π {f}_{d 2} t + φ )$$

$${V}_{2 B} ( t ) = {A}_{2} ( t ) sin ( 2 π {f}_{d 2} t + π + φ )$$

Here, f_{d2} is a driving frequency (hereinafter, referred to as a second driving frequency). A₂ (t) is an amplitude voltage that changes depending on time t. A phase difference between the driving voltage waveform V_{2A} (t) and the driving voltage waveform V_{2B} (t) is π (that is, 180°). In addition, q is the phase difference between the driving voltage waveforms V_{1A} (t) and V_{1B} (t) and the driving voltage waveforms V_{2A} (t) and V_{2B} (t). In the present embodiment, φ=π/2 (that is, 90°) is set in order to cause the mirror portion 20 to perform precession.

The first driving frequency f_{d1} is set so as to match the resonance frequency around the first axis a₁ of the mirror portion 20. The second driving frequency f_{d2} is set so as to match the resonance frequency around the second axis a₂ of the mirror portion 20. The first driving frequency f_{d1} is substantially equal to the second driving frequency f_{d2}.

By linearly changing the amplitude voltages A₁ (t) and A₂ (t) with respect to time t, the trajectory of the light beam LB reflected by the mirror portion 20 is a spiral trajectory in which the radius vector changes. By setting the amplitude voltages A₁ (t) and A₂ (t) to constant values that do not depend on time t, the trajectory of the light beam LB reflected by the mirror portion 20 is a circular trajectory of which the radius vector is constant.

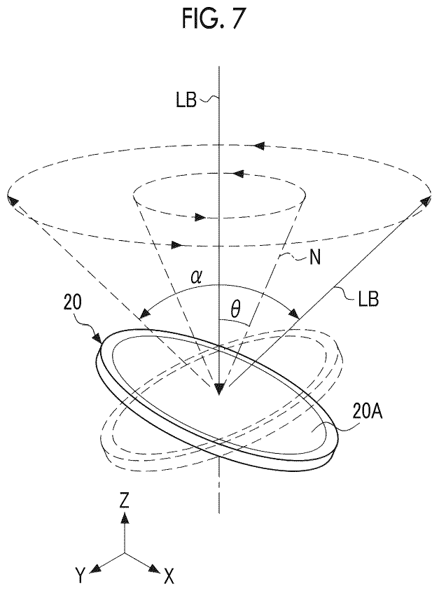

FIG. 7 shows a state in which the mirror portion 20 performs precession. In a case where a deflection angle of the mirror portion 20 is denoted by θ, a scan angle (full angle) a of the light beam LB is four times the deflection angle θ. The deflection angle θ refers to an angle formed by the normal line N of the reflecting surface 20A with respect to the Z direction.

As described above, by providing the reinforcing structure 51 in the movable frame 22, the spring constant (that is, the stiffness) of the movable frame 22 constituting the gimbal structure is increased, and the mass of the gimbal structure is increased. In addition, the resonance Q value increases as the mass of the gimbal structure increases.

In principle, in a case where the diameter of the mirror portion 20 is increased, the inertia moment of the mirror is increased, so that the resonance frequency is decreased and the deflection angle θ is decreased. However, in the present embodiment, since the reinforcing structure 51 is provided in the movable frame 22, the distortion of the movable frame 22 is reduced, and the decrease in the resonance frequency and the deflection angle θ is suppressed, so that the diameter of the mirror portion 20 can be increased. That is, according to the present embodiment, the diameter, the operation frequency, and the deflection angle θ of the mirror portion 20 can be increased, and the detection distance, the resolution, and the detection range as the performance index of the distance measurement by the LiDAR device are improved.

In addition, as will be described in detail later, in a case where the mirror portion 20 performs precession, stress is concentrated on a boundary portion K between the movable frame 22 and the first support portion 21. However, in the present embodiment, since the reinforcing structure 51 is not in contact with the boundary portion K, the concentration of the stress on the boundary portion K is suppressed, and the structural destruction at the boundary portion K is suppressed.

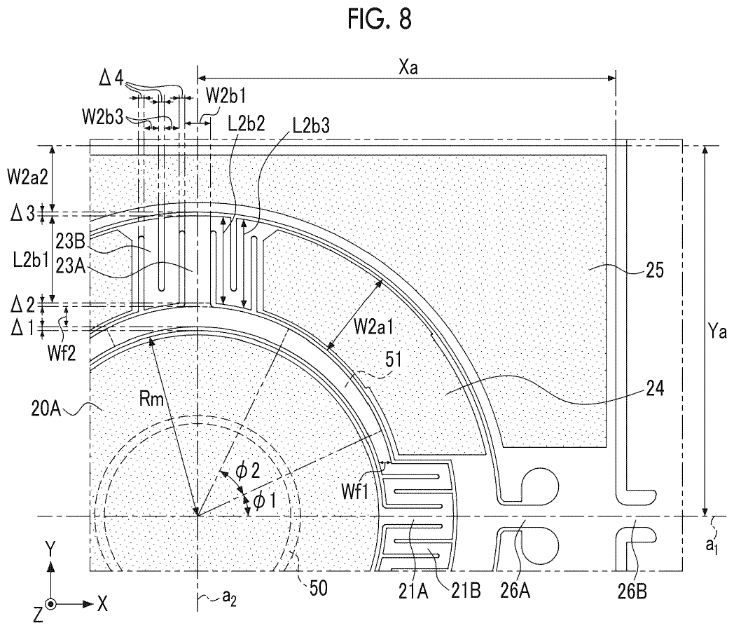

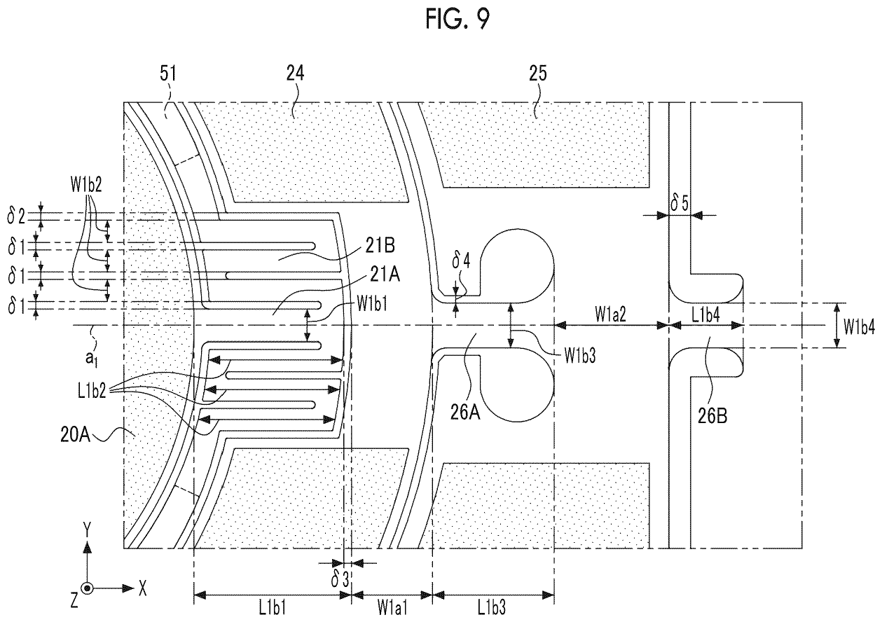

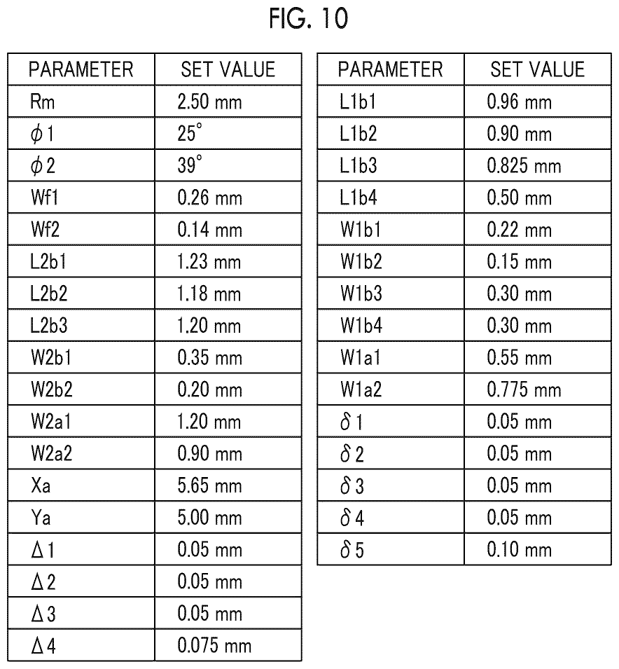

In order to verify the above-described effect, the present applicant produced a sample of MMD2 and performed an experiment. FIGS. 8 and 9 show parameters relating to the width, length, and the like of the components of the sample used in the experiment. FIG. 10 is a diagram showing specific set values of the parameters.

In addition, the diameter of the mirror portion 20 was set to 5 mm, the thickness of the SOI substrate 30 was set to 430 μm, and the thickness of the second silicon active layer 33 was set to 80 μm. The diameter of the mirror portion 20 is larger than the diameter of the mirror portion of the MMD used in augmented reality (AR) glasses or the like. In addition, in the present experiment, f_{d1}=1475 Hz and f_{d2}=1445 Hz.

In the present experiment, the mirror portion 20 was resonantly driven in the anti-phase rotation mode around the second axis a₂ in the atmosphere, and the driving voltage (that is, the amplitude voltage) required for α=40° was confirmed. As a result of the experiment, the driving voltage required for α=40° was 23 V.

In addition, the mirror portion 20 was caused to perform precession to draw a perfect circle at α=40°, and the time from the start of the operation to the occurrence of the failure in the MMD2 (hereinafter, referred to as continuous driveable time) was confirmed. As a result of the experiment, no destruction occurred even in a case where the MMD2 was operated for 1000 hours. That is, the continuous driveable time was 1000 hours or more.

### Second Embodiment

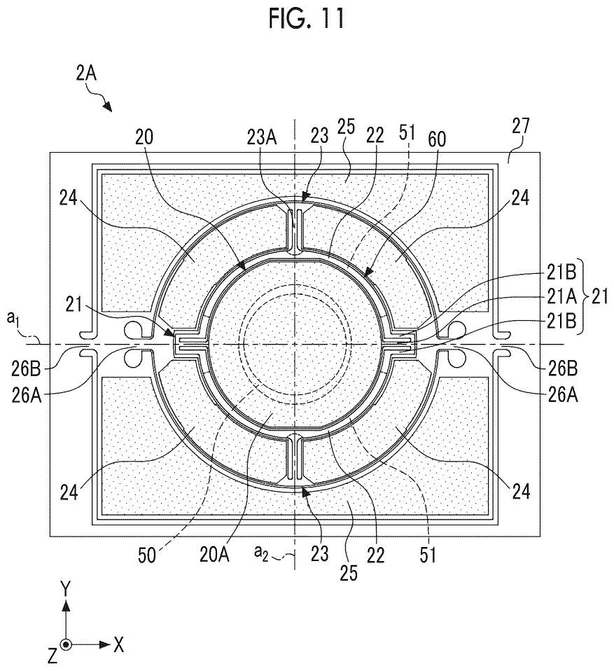

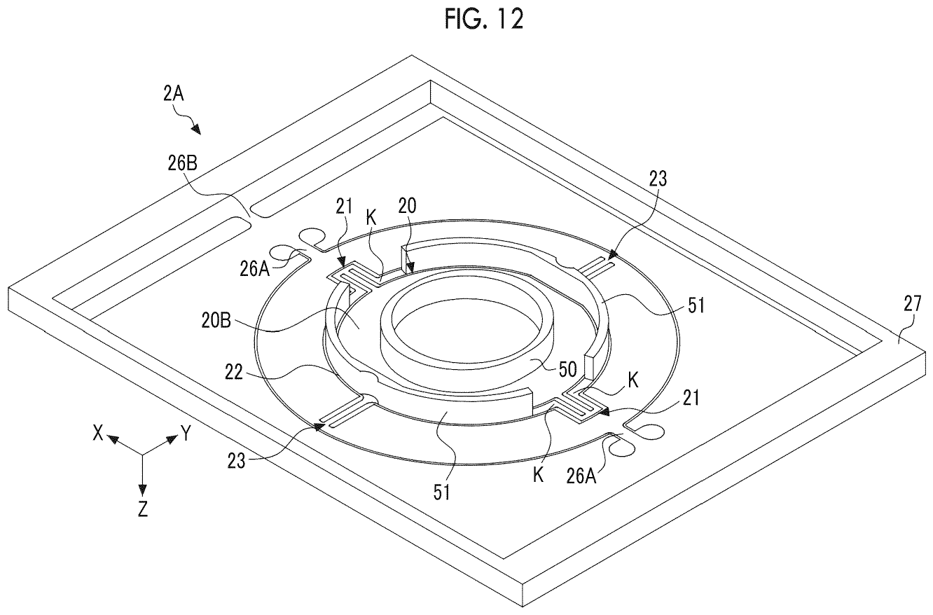

Next, a second embodiment will be described. FIG. 11 is a plan view of the MMD 2A according to the second embodiment as viewed from the light incident side. FIG. 12 is a perspective view of the MMD 2A according to the second embodiment as viewed from a back surface side. The MMD 2A is different from the MMD 2 according to the first embodiment in the configurations of the first support portion 21, the second support portion 23, and the reinforcing structure 51.

In the present embodiment, the first support portion 21 is configured with a swing shaft 21A and a pair of coupling parts 21B. The coupling part 21B does not have the bent portion B unlike the first embodiment. One end of the coupling part 21B is connected to an outer end portion of the swing shaft 21A on the first axis a₁, and the other end of the coupling part 21B is connected to the movable frame 22. Specifically, the coupling part 21B extends from the outer end portion of the swing shaft 21A on the first axis a₁ toward the mirror portion 20 and is connected to the movable frame 22 in a region adjacent to the mirror portion 20.

In the present embodiment, the second support portion 23 is not provided with the coupling part 23B and is composed of only the swing shaft 23A that extends along the second axis a₂. One end of the swing shaft 23A is connected to the movable frame 22, and the other end thereof is connected to the first actuator 24 in a region adjacent to the second actuator 25.

In the present embodiment, one reinforcing structure 51 is provided in each of the pair of movable frames 22. The reinforcing structure 51 extends to a region adjacent to the second support portion 23 of the movable frame 22, unlike the first embodiment. However, the reinforcing structure 51 is not in contact with the boundary portion K between the movable frame 22 and the first support portion 21, as in the first embodiment.

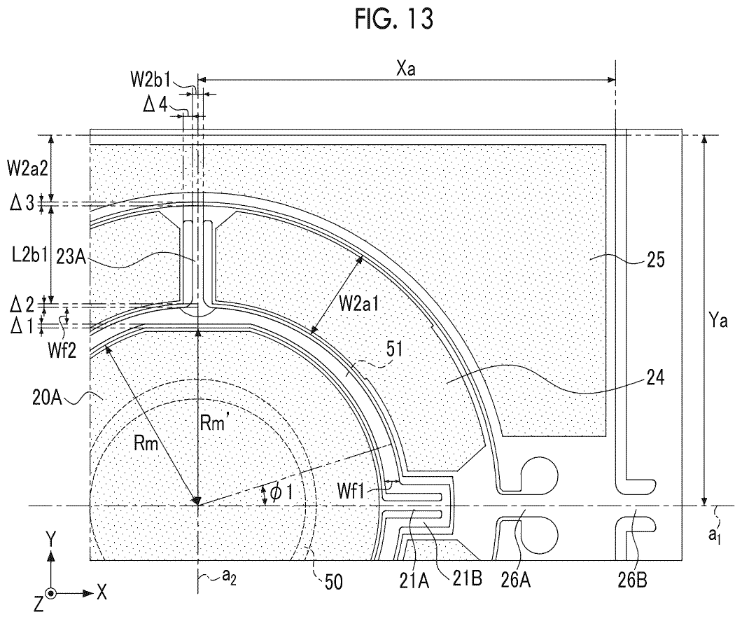

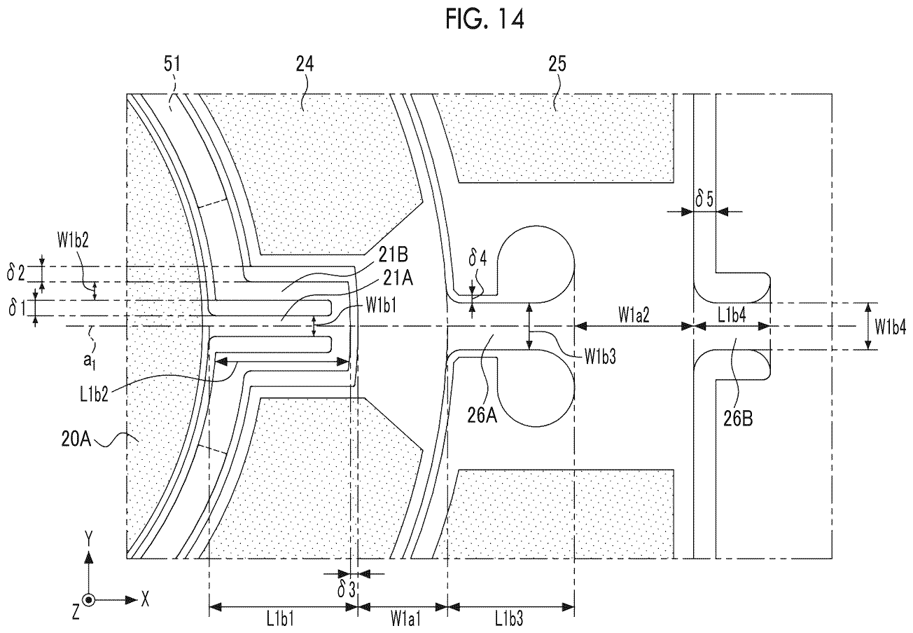

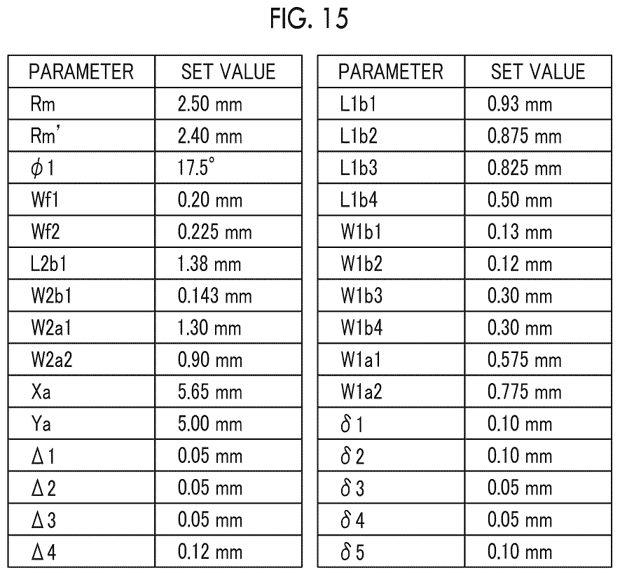

The present applicant also performed the same experiment as described above on the MMD 2A according to the second embodiment. FIGS. 13 and 14 show parameters relating to the width, length, and the like of the components of the sample used in the experiment. FIG. 15 is a diagram showing specific set values of the parameters.

In addition, the diameter of the mirror portion 20 was set to 5 mm, the thickness of the SOI substrate 30 was set to 430 μm, and the thickness of the second silicon active layer 33 was set to 80 μm. In addition, in the present experiment, f_{d1}=1513 Hz and f_{d2}=1483 Hz.

As a result of the experiment, in a case where the mirror portion 20 was resonantly driven in the anti-phase rotation mode around the second axis a₂ in the atmosphere, the driving voltage required for α=40° was 13 V. In addition, in a case where the mirror portion 20 was caused to perform precession to draw a perfect circle at α=40°, no failure occurred in the MMD 2A in less than 1000 hours. That is, the continuous driveable time was 1000 hours or more.

### First Comparative Example

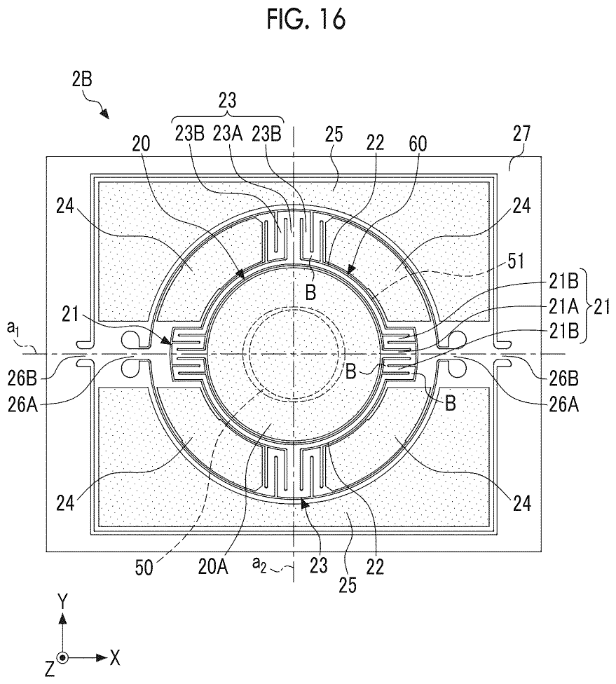

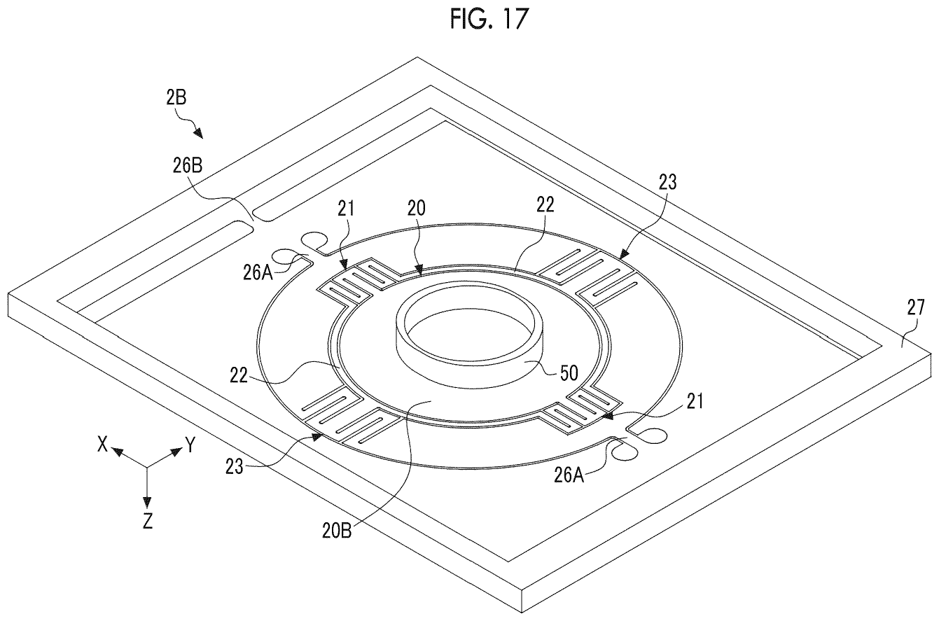

Next, the first comparative example will be described. FIG. 16 is a plan view of the MMD 2B according to the first comparative example as viewed from the light incident side. FIG. 17 is a perspective view of the MMD 2B according to the first comparative example as viewed from a back surface side. The MMD 2B is different from the configuration of the MMD 2 according to the first embodiment in that the reinforcing structure 51 is not provided in the movable frame 22.

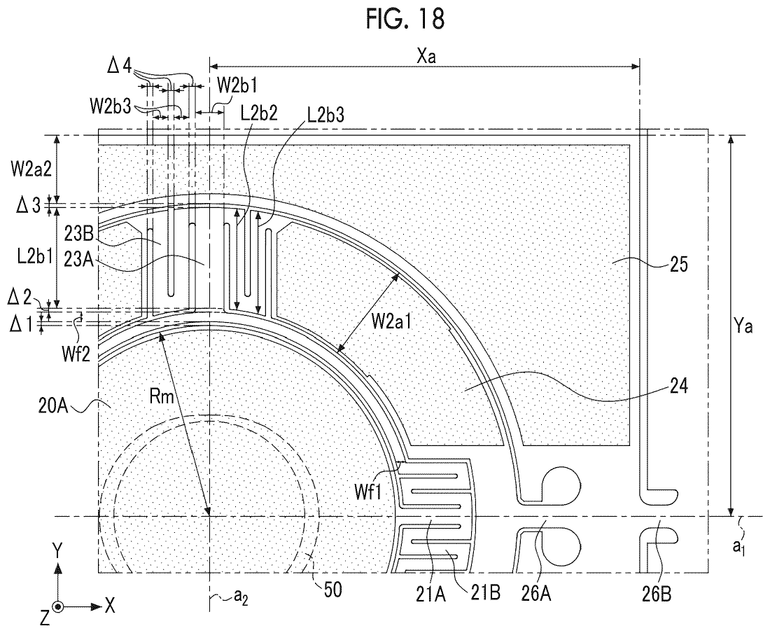

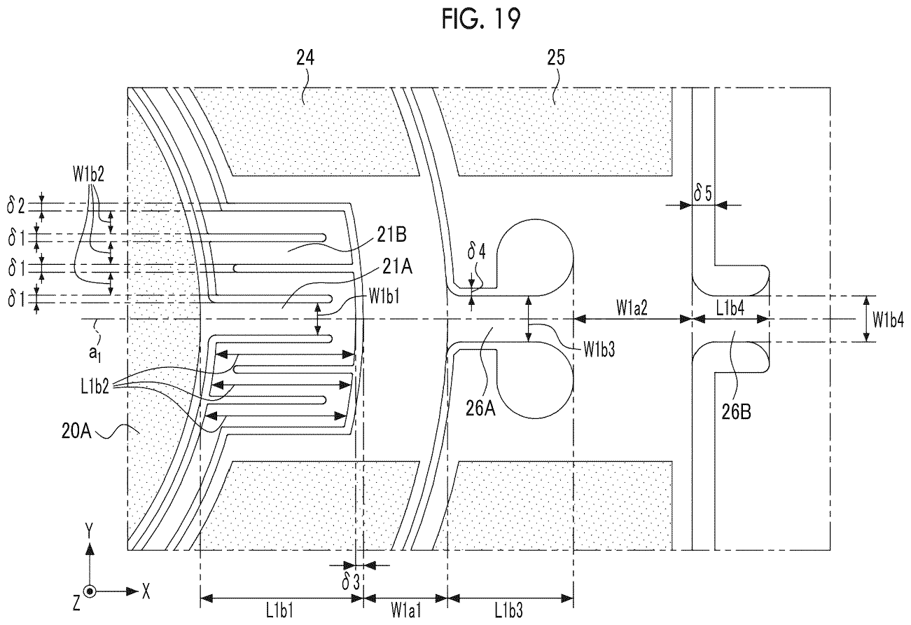

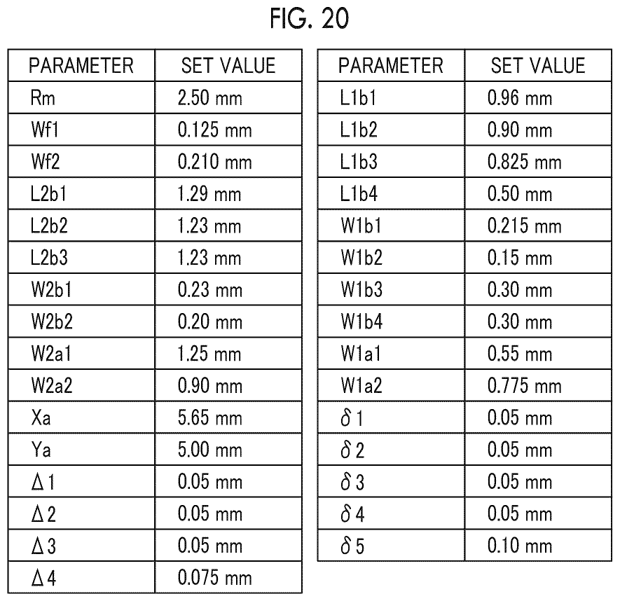

The present applicant also performed the same experiment as described above on the MMD 2B according to the first comparative example. FIGS. 18 and 19 show parameters relating to the width, length, and the like of the components of the sample used in the experiment. FIG. 20 is a diagram showing specific set values of the parameters.

In addition, the diameter of the mirror portion 20 was set to 5 mm, the thickness of the SOI substrate 30 was set to 430 μm, and the thickness of the second silicon active layer 33 was set to 80 μm. In addition, in the present experiment, f_{d1}=1443 Hz and f_{d2}=1446 Hz.

As a result of the experiment, in a case where the mirror portion 20 was resonantly driven in the anti-phase rotation mode around the second axis a₂ in the atmosphere, the driving voltage required for α=40° was 38 V. In addition, in a case where the mirror portion 20 was caused to perform precession to draw a perfect circle at α=40°, the piezoelectric film was destroyed in less than 200 hours. That is, the continuous driveable time was less than 200 hours.

### Second Comparative Example

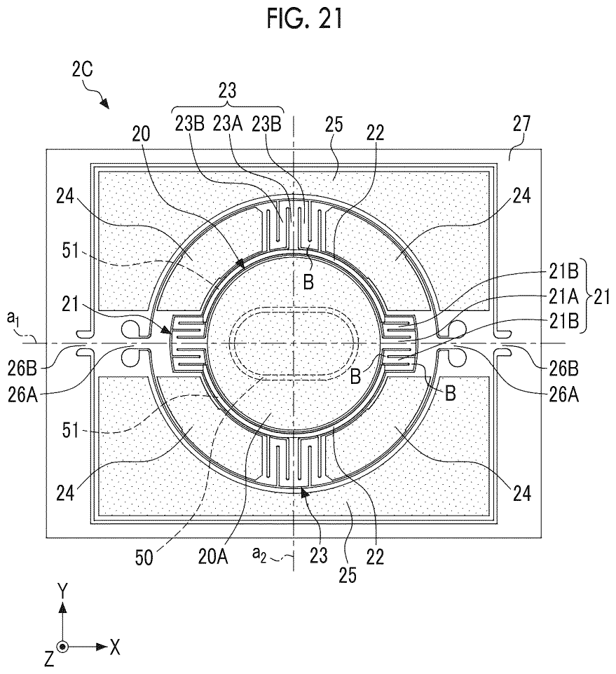

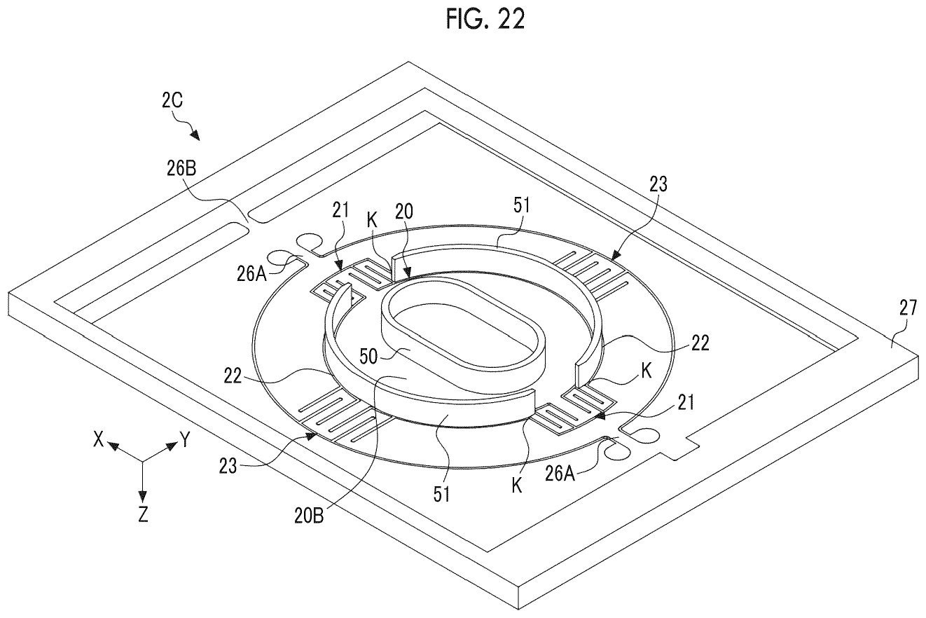

Next, a second comparative example will be described. FIG. 21 is a plan view of the MMD 2C according to the second comparative example as viewed from the light incident side. FIG. 22 is a perspective view of the MMD 2C according to the second comparative example as viewed from a back surface side. The MMD 2C is different from the configuration of the MMD 2A according to the second embodiment in that the reinforcing structure 51 provided in the movable frame 22 extends to the boundary portion K between the movable frame 22 and the first support portion 21 and is in contact with the boundary portion K. In addition, in the second comparative example, the rib 50 is formed in a stadium shape in order to bring the resonance frequency around the first axis a₁ and the resonance frequency around the second axis a₂ closer to each other. The rib 50 is longer in the X direction than in the Y direction.

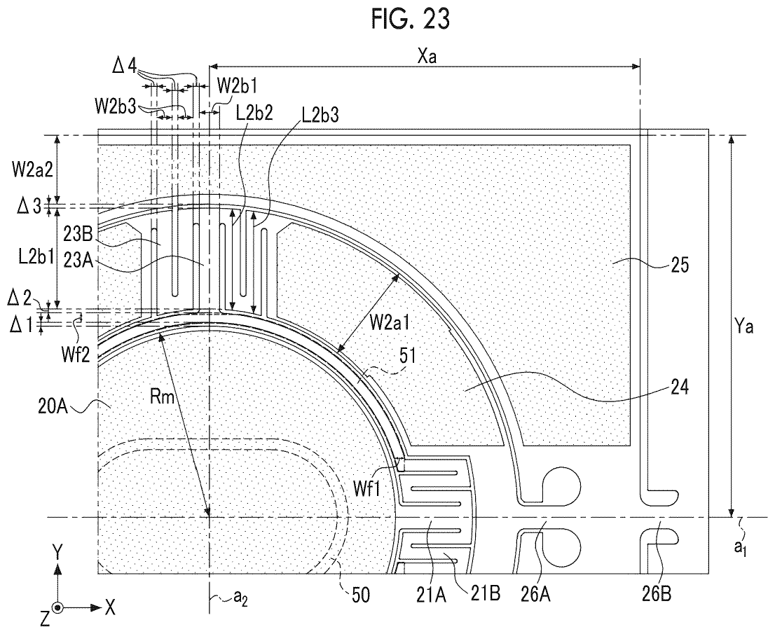

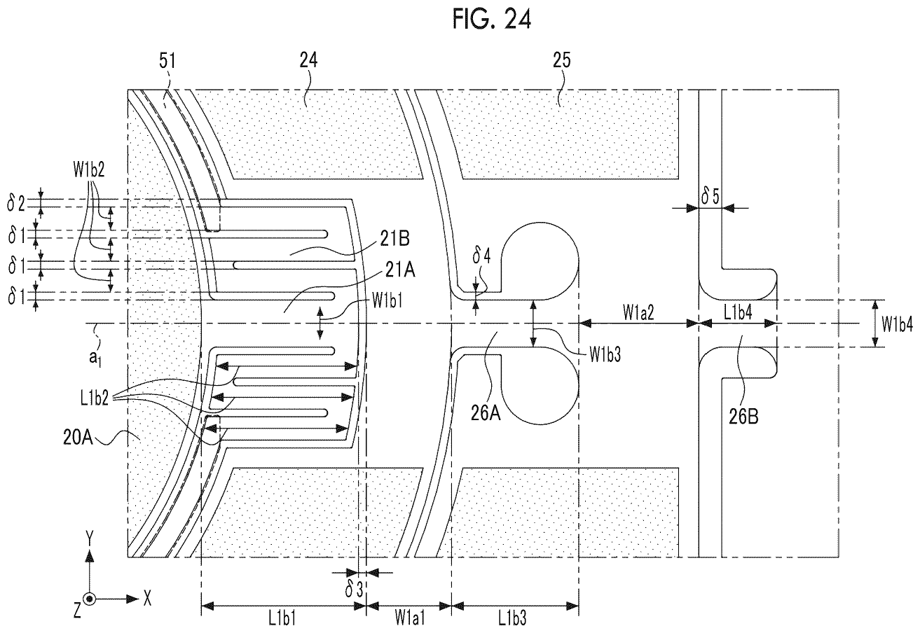

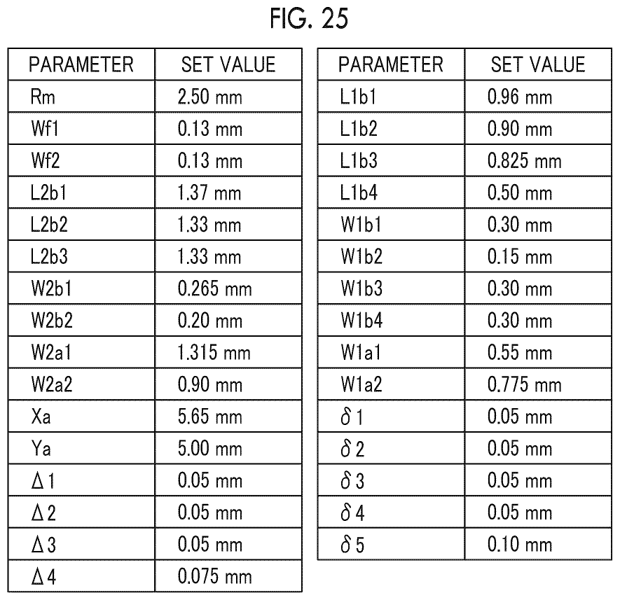

The present applicant also performed the same experiment as described above on the MMD 2B according to the first comparative example. FIGS. 23 and 24 show parameters relating to the width, length, and the like of the components of the sample used in the experiment. FIG. 25 is a diagram showing specific set values of the parameters.

In addition, the diameter of the mirror portion 20 was set to 5 mm, the thickness of the SOI substrate 30 was set to 430 μm, and the thickness of the second silicon active layer 33 was set to 80 μm. In addition, in the present experiment, f_{d1}=1487 Hz and f_{d2}=1457 Hz.

As a result of the experiment, in a case where the mirror portion 20 was resonantly driven in the anti-phase rotation mode around the second axis a₂ in the atmosphere, the driving voltage required for α=40° was 16 V. In addition, in a case where the mirror portion 20 was caused to perform precession to draw a perfect circle at α=40°, structural destruction occurred at the boundary portion K between the movable frame 22 and the first support portion 21 in less than 20 hours. That is, the continuous driveable time was less than 20 hours.

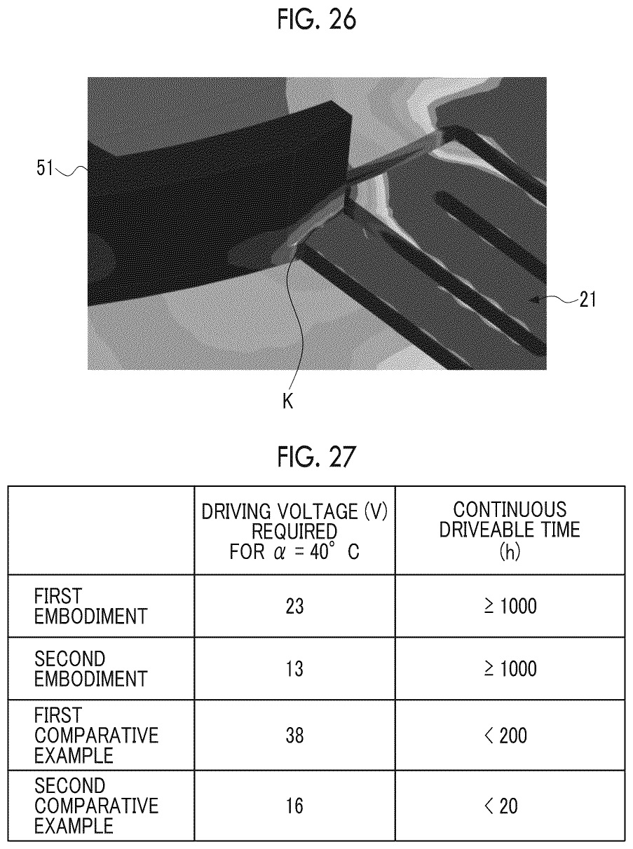

FIG. 26 is a stress distribution diagram showing a distribution of stress in the vicinity of the boundary portion K generated by the simulation. According to the stress distribution diagram, it can be seen that, in a case where the mirror portion 20 was caused to perform precession, the stress generated by the swing of the mirror portion 20 around the first axis a₁ is concentrated on the boundary portion K between the end portion of the reinforcing structure 51 and the first support portion 21. It is considered that the structural destruction occurs in the boundary portion K due to the concentration of the stress.

### CONCLUSION

FIG. 27 shows experimental results according to each of the embodiments and each of the comparative examples described above. In the use application of LiDAR, one indicator is that α≥40° can be achieved in helical scanning. In addition, in the use application of LiDAR, one indicator is that the continuous driveable time is 1000 hours or more.

In the first comparative example, since the reinforcing structure 51 is not provided in the movable frame 22, the stiffness of the gimbal structure is low. Therefore, the driving voltage required for α=40° was large, and was 38 V. In a case where such a large driving voltage is applied to the driving part, not only the power consumption increases, but also the probability of electrical destruction occurring in the piezoelectric film increases during continuous driving. In the first comparative example, in a case where the driving voltage was set to 38 V and the mirror portion 20 was caused to perform precession to draw a perfect circle at α=40°, the piezoelectric film was destroyed in less than 200 hours. That is, the continuous driveable time was less than 200 hours.

In the second comparative example, since the reinforcing structure 51 is provided in the movable frame 22, the stiffness of the gimbal structure is high. Therefore, the driving voltage required for α=40° was low, and was 16 V. However, in the second comparative example, since the reinforcing structure 51 is in contact with the boundary portion K between the movable frame 22 and the first support portion 21, the structural destruction occurred in the boundary portion K in less than 20 hours in a case where the mirror portion 20 was caused to perform precession to draw a perfect circle at α=40°. That is, the continuous driveable time was less than 20 hours.

On the other hand, in the first embodiment and the second embodiment, the reinforcing structure 51 is provided in the movable frame 22, and the reinforcing structure 51 is in contact with the boundary portion K. Accordingly, in the first embodiment and the second embodiment, the required driving voltage at α=40° was low, and the continuous driveable time in a case where the mirror portion 20 was caused to perform precession to draw a perfect circle at α=40° was 1000 hours or more.

In the above embodiment, the hardware configuration of the driving controller 4 can be variously modified. The processing unit of the driving controller 4 may be composed of one processor or may be composed of a combination of two or more processors of the same type or different types. The processor includes, for example, a CPU, a programmable logic device (PLD), or a dedicated electric circuit. As is well known, the CPU is a general-purpose processor that executes software (program) to function as various processing units. The PLD is a processor such as a field programmable gate array (FPGA) whose circuit configuration can be changed after manufacture. The dedicated electric circuit is a processor that has a dedicated circuit configuration designed to perform a specific process, such as an application specific integrated circuit (ASIC).

All of the publications, the patent applications, and the technical standards described in the specification are incorporated by reference herein to the same extent as each individual document, each patent application, and each technical standard are specifically and individually stated to be incorporated by reference.

What is claimed is:

1. A micromirror device comprising:
a mirror portion that has a reflecting surface for reflecting incident light;
a pair of first support portions that are connected to the mirror portion on a first axis located in a plane including the reflecting surface in a stationary state of the mirror portion and that support the mirror portion to be swingable around the first axis;
a pair of movable frames that are connected to the first support portions and that face each other across the first axis;
a pair of second support portions that are connected to the movable frames on a second axis located in the plane and perpendicular to the first axis and that support the mirror portion, the first support portions, and the movable frames to be swingable around the second axis;
a pair of first actuators that are connected to the second support portions and face each other across the second axis;
a pair of second actuators that are disposed to surround the first actuator and face each other across the first axis;
a fixed frame that is disposed to surround the second actuator;
a pair of first connecting portions that connect the first actuator and the second actuator; and
a pair of second connecting portions that connect the second actuator and the fixed frame,
wherein the movable frame is line-symmetrical with respect to the first axis and has a reinforcing structure that is not in contact with a boundary portion between the movable frame and the first support portion, and
the first connecting portion and the second connecting portion each have a line-symmetrical shape with respect to the first axis and support the first actuator and the second actuator to be swingable around the first axis.

2. The micromirror device according to claim 1,
wherein a combined thickness of the movable frame and the reinforcing structure is equal to a thickness of the fixed frame.

3. The micromirror device according to claim 2,
wherein the reinforcing structure is provided on a back surface side of the movable frame.

4. The micromirror device according to claim 1,
wherein the first actuator and the second actuator each have a piezoelectric element.

5. The micromirror device according to claim 1,
wherein the first support portion includes
a first swing shaft having a shape that is line-symmetrical about the first axis and disposed on the first axis, and
a pair of first coupling parts disposed at positions facing each other across the first axis,
one end of the first swing shaft is connected to the mirror portion and the other end of the first swing shaft is connected to the first coupling part, and
one end of the first coupling part is connected to an outer end portion of the first swing shaft on the first axis and the other end of the first coupling part is connected to the movable frame.

6. The micromirror device according to claim 5,
wherein the first coupling part extends in a direction from the outer end portion of the first swing shaft on the first axis toward the mirror portion, is bent in an outer circumferential direction in a region adjacent to the mirror portion, and is bent again in a region adjacent to the first actuator to be connected to the movable frame.

7. The micromirror device according to claim 5,
wherein the second support portion includes
a second swing shaft having a shape that is line-symmetrical about the second axis and disposed on the second axis, and
a pair of second coupling parts disposed at positions facing each other across the second axis,
one end of the second swing shaft is connected to the movable frame and the other end of the second swing shaft is connected to the second coupling part, and
one end of the second coupling part is connected to an outer end portion of the second swing shaft on the second axis and the other end of the second coupling part is connected to the first actuator.

8. The micromirror device according to claim 7,
wherein the second coupling part extends in a direction from the outer end portion of the second swing shaft on the second axis toward the mirror portion, is bent in an outer circumferential direction in a region adjacent to the movable frame, and is connected to the first actuator in a region adjacent to the second actuator.

9. An optical scanning device comprising:
the micromirror device according to claim 1; and
a processor that drives the first actuator and the second actuator,
wherein the processor applies a drive signal to the first actuator and the second actuator to cause the mirror portion to swing around each of the first axis and the second axis.
